(19) United States
(12) Patent Application Publication
(10) Pub. No.: US 2010/0105168 A1
(43) Pub. Date: Apr. 29, 2010

(54) MICROELECRONIC ASSEMBLY AND METHOD FOR FORMING THE SAME

(75) Inventors: Chandrasekaram Ramiah, Phoenix, AZ (US); Lianjun Liu, Chandler, AZ (US); Michael F. Petras, Phoenix, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 12/260,603

(22) Filed: Oct. 29, 2008

(51) Int. Cl. H01L 21/58

(52) U.S. Cl. 438/107; 361/728

(57) ABSTRACT

A microelectronic assembly and a method for forming a microelectronic assembly are provided. First and second substrates (32, 68) are provided. Each substrate has first and second opposing sides. The first substrate (32) has a first microelectronic device formed on the first side (46) thereof, and the second substrate (68) has a second microelectronic device formed on the first side (82) thereof. The first and second substrates (32, 68) are interconnected with at least one support member (100) such that the at least one support member (100) is positioned between the second side (48) of the first substrate (32) and the first side (82) of the second substrate (68). At least one conductive member (98) is provided that electrically connects the first microelectronic device to the second microelectronic device.

### FIELD OF THE INVENTION

The present invention generally relates to a microelectronic assembly and a method for forming a microelectronic assembly, and more particularly relates to a microelectronic assembly having a support member interconnecting separate substrates.

### BACKGROUND OF THE INVENTION

Integrated circuits are formed on semiconductor substrates, or wafers. The wafers are then sawed into microelectronic dies (or “dice”), or semiconductor chips, with each die carrying, for example, a respective integrated circuit (e.g., a microprocessor) or a microelectromechanical system (MEMS) device (e.g., an accelerometer). In some examples, each semiconductor chip is mounted to a package or carrier substrate using either wirebonding or “flip-chip” connections. The packaged chip is then typically mounted to a circuit board, or motherboard, before being installed in a system, such as an electronic or a computing system.

Often it is desirable to integrate a MEMS device with an integrated circuit (e.g., a microprocessor to interpret the signals generated by the MEMS device) that is formed using convention semiconductor processing techniques, such as complementary metal-oxide semiconductor (CMOS) processing steps. One approach for such integration involves the use of a cap wafer attached to the MEMS die with a seal (or “frit”) to form a cavity to protect the MEMS device, as is often required. Another approach is the use of processing techniques that are compatible with methods used to form the MEMS device (i.e., “MEMS friendly processing techniques), such as bipolar CMOS processing. A third approach utilizes through vias (i.e., electrical connectors) formed through the integrated circuit die, which are connected to the MEMS device by soldering.

Each of the above mentioned integration methods described above may have at least one considerably undesirable characteristic. For example, the cap wafers and frits significantly add to the cost of the assembly. Additionally, due to the possibility that the frit may contaminate the MEMS device element (e.g., a proof mass), the frits are often intentionally oversized to provide a relatively large gap between the frit and the MEMS device, which adds to the overall size of the assembly. The use of MEMS friendly processing techniques significantly increases the manufacturing costs of the integrated circuit, while the through vias increase both manufacturing time and costs.

Accordingly, it is desirable to provide an improved method for integrating multiple die (e.g., such as an integrated circuit and a MEMS device). Other desirable features and characteristics of the invention will become apparent from the subsequent detailed description and the appended claims, taken in conjunction with the accompanying drawings and the foregoing technical field and background.

### BRIEF DESCRIPTION OF THE DRAWINGS

The various embodiments will hereinafter be described in conjunction with the following drawings, wherein like numerals denote like elements, and

FIG. 1 is a top plan view of a semiconductor substrate;

FIG. 2 is a cross-sectional side view of a microelectronic die having an integrated circuit formed thereon;

FIG. 3 is simplified cross-sectional side view of the microelectronic die of FIG. 2;

FIG. 4 is a cross-sectional side view of the microelectronic die of FIG. 3 with a carrier substrate attached thereto;

FIG. 5 is a cross-sectional side view of the microelectronic die of FIG. 4 after having undergone a thinning process;

FIGS. 6 and 7 are cross-sectional side views of the microelectronic die of FIG. 5 illustrating the formation of a first component of a structural support member thereon;

FIG. 8 is a cross-sectional side view of the microelectronic die of FIG. 8 after the carrier substrate has been removed therefrom;

FIGS. 9 and 10 are cross-sectional side views of a second microelectronic die having a microelectromechanical system (MEMS) device formed thereon, illustrating the formation the formation of a second component of the structural support member thereon;

FIG. 11 is a cross-sectional side view of a microelectronic assembly according to one embodiment of the present invention; and

FIG. 12 is a top plan view of the microelectronic assembly of FIG. 11.

### DETAILED DESCRIPTION OF THE INVENTION

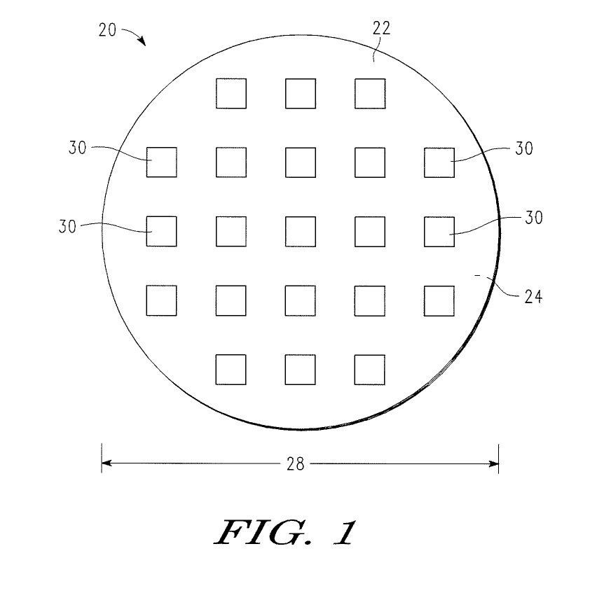

The following detailed description is merely exemplary in nature and is not intended to limit the invention or application and uses of the invention. Furthermore, there is no intention to be bound by any expressed or implied theory presented in the preceding technical field, background, brief summary, or the following detailed description. It should also be noted that FIGS. 1-12 are merely illustrative and may not be drawn to scale.

FIG. 1 to FIG. 12 illustrate a microelectronic assembly and a method for forming a microelectronic assembly. First and second substrates are provided. Each substrate has first and second opposing sides. The first substrate has a first microelectronic device formed on the first side thereof, and the second substrate has a second microelectronic device formed on the first side thereof. The first and second substrates are interconnected with at least one support member such that the at least one support member is positioned between the second side of the first substrate and the first side of the second substrate. At least one conductive member is provided that electrically connects the first microelectronic device to the second microelectronic device.

In one embodiment, the first microelectronic device is an integrated circuit (e.g., a microprocessor, a digital logic or analog circuit transducer), and the second microelectronic device is a microelectromechanical system (MEMS) device. Examples of MEMS devices include accelerometers and switches. The structural support member and the first and second substrates may form a cavity in which a MEMS device element is located.

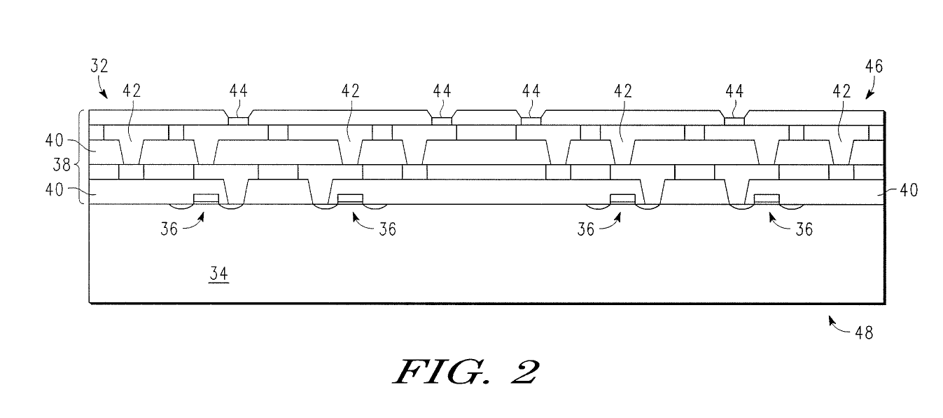

Referring to FIGS. 1 and 2, there is illustrated a semiconductor substrate 20 on which various types of microelectronic devices (e.g., integrated circuits and MEMS devices) may be formed. The semiconductor substrate 20 is made of a semiconductor material, such as gallium arsenide (GaAs), gallium nitride (GaN), or silicon (Si). The substrate 20 has an upper surface 22, a lower surface 24, and a thickness (not shown) of, for example, between approximately 300 and 1000 micrometers (μm). The semiconductor material of the substrate 20 may be of a first conductivity type, or doped with a first dopant type (e.g., P-type). The substrate 20 may be a semiconductor wafer with a diameter 28 of, for example, approximately 150, 200, or 300 millimeters (mm). As illustrated specifically in FIG. 1, the substrate 20 is divided into multiple dies 30, or “dice.” As will be described in greater detail below, each die 30 may have an at least partially formed microelectronic device formed thereon. In other embodiments, the dies 30 may be spaced closer together than as shown in FIG. 1.

FIG. 2 illustrates an integrated circuit (IC) die 32, according to one embodiment of the present invention. The IC die 32 may be formed on a substrate similar to that shown in FIG. 1 (i.e., the IC die 32 may be one of a particular type of the dies 30 formed on the substrate 20). Although the following process steps may be shown as being performed on only one die 32, it should be understood that each of the steps may be performed on substantially the entire substrate on which the IC die 32 is formed (e.g., the substrate 20 or multiple dice 30), simultaneously.

In the depicted embodiment, the IC die 32 includes a substrate portion 34, with multiple semiconductor devices 36 formed thereon, and a build-up (or backend) layer 38 formed over the substrate portion 34 and the semiconductor devices 36. In the embodiment shown, the substrate portion 34 is in a bulk semiconductor configuration but in other embodiments may be in, for example, a semiconductor-on-insulator configuration. The semiconductor devices 36 are, for example, semiconductor transistors that include source regions, drain regions, and gate formations (including a gate electrode and a gate dielectric layer), as is commonly understood, and may at least partially form an integrated circuit (along other various components such as resistors, capacitors, and inductors), such as a microprocessor or an application specific integrated circuit (ASIC). The integrated circuit may be formed using, for example, masking (e.g., lithography), reactive ion etching (RIE), physical sputtering, damascene patterning, physical vapor deposition, electroplating, and chemical vapor (CVD), low pressure chemical vapor (LPCVD), and/or plasma enhanced chemical vapor deposition (PECVD) techniques. For example, the integrated circuit may be manufactured using complementary metal-oxide semiconductor (CMOS) processing techniques.

The build-up layer 38 includes various insulating layers (e.g., interlayer dielectric layers) 40, conductive members 42 (e.g., traces and through vias), and bond pads 44. The insulating layers 40 are made of, for example, silicon oxide (SiO2), silicon nitride (SiN), tetraethylorthosilicate (TEOS), and/or borophosphosilicate tetraethylorthosilicate (BPTEOS) and formed using CVD, LPCVD, and/or PECVD. The bond pads 44 are formed on an upper surface of the build-up layer 38 to provide an electrical connection to the integrated circuit through the conductive members 42. Still referring to FIG. 2, the IC die 32 (and/or the substrate portion 34) also has a first side (or surface) 46 and a second, opposing side 48. The first (or upper) side 46 may be referred to as an “active” or “device” side, as it is the side of the IC die (and/or the substrate portion 34) on which the semiconductor devices 36 (i.e., the integrated circuit) is formed. Likewise, the second (or lower) side 48 may be referred to as an “inactive” or “non-device” side.

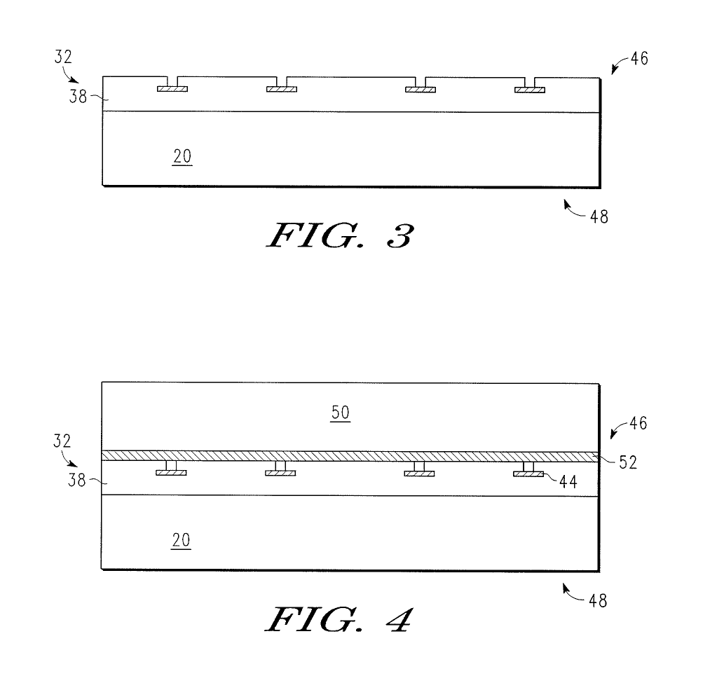

As shown in FIGS. 3 and 4, which illustrate the IC die 32 in a simplified form, a carrier (or support substrate) 50 is attached to the first side 46 of the IC die 32 with, for example, a ultraviolet (UV) cured adhesive layer 52. The carrier substrate 50 may be made of glass. As indicated in FIG. 5, the IC die 32 is then thinned (e.g., after being flipped such that the second side 48 faces up). More particularly, the substrate portion 20 is thinned from an initial thickness 54 to a reduced thickness 56. The thinning may be performed using a grinding or polished head (not shown), as is commonly understood.

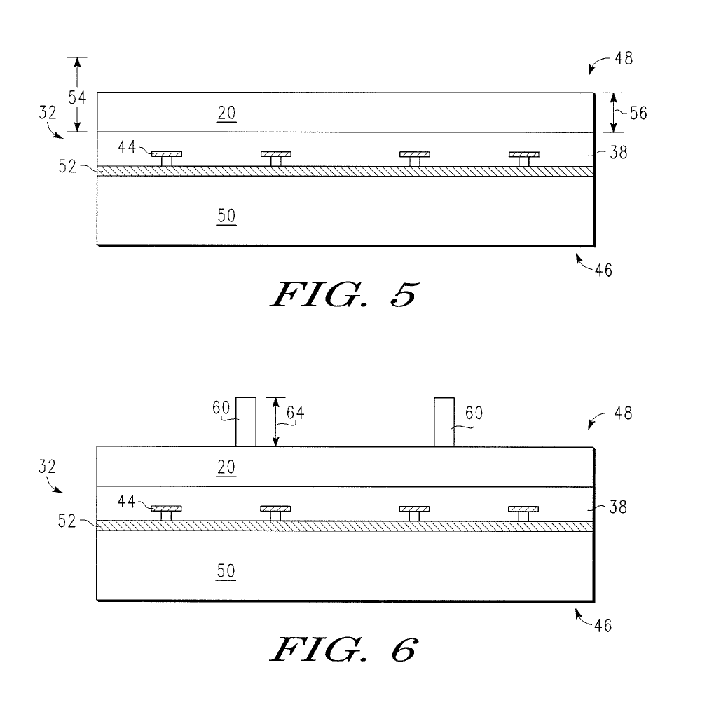

Referring now to FIGS. 6 and 7, a first structural support component 58 is then formed on the second side 48 of the IC die 32 over the substrate portion 20. The first structural support component 58 includes a first portion 60 and a second portion 62, each of which may be substantially annular in shape (i.e., ring-shaped). In one embodiment, the first portion 60 is made of gold (Au) and has a height 64 of approximately 20 μm, and the second portion 62 is made of tin (Sn) and has a thickness 66 of between 1 and 3 μm (i.e., such that the first structural support component has an overall height of between 21 and 23 μm). Both the first and second portions 60 and 62 may be formed using sputtering or evaporation together with electroplating and lithography processes, as are commonly understood. Although not shown, it should be understood that a thin (e.g., 2000 Angstroms (Å)) seed layer of, for example, titanium tungsten (TiW) may be formed on the second side 48 of the IC die 32 prior to the formation of the first structural support component 58.

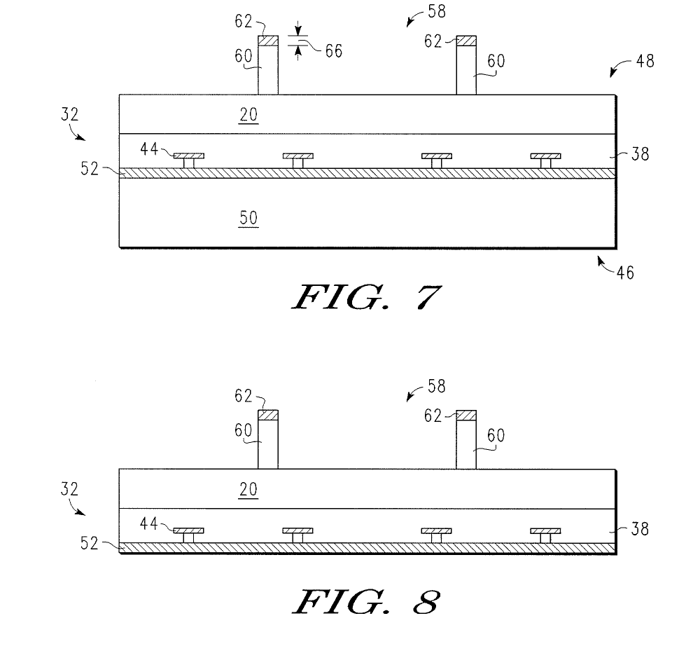

As shown in FIG. 8, the carrier substrate 50 is then removed from the IC die 32 using known techniques. The IC die 32 may then be singulated from its respective substrate via sawing or dicing (e.g., using a diamond saw and a pick and place machine).

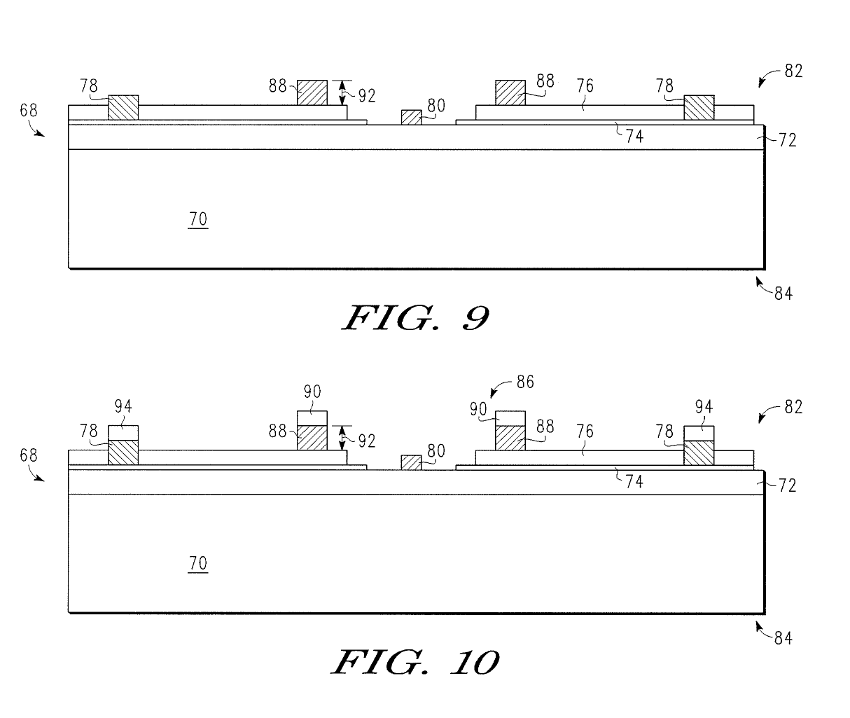

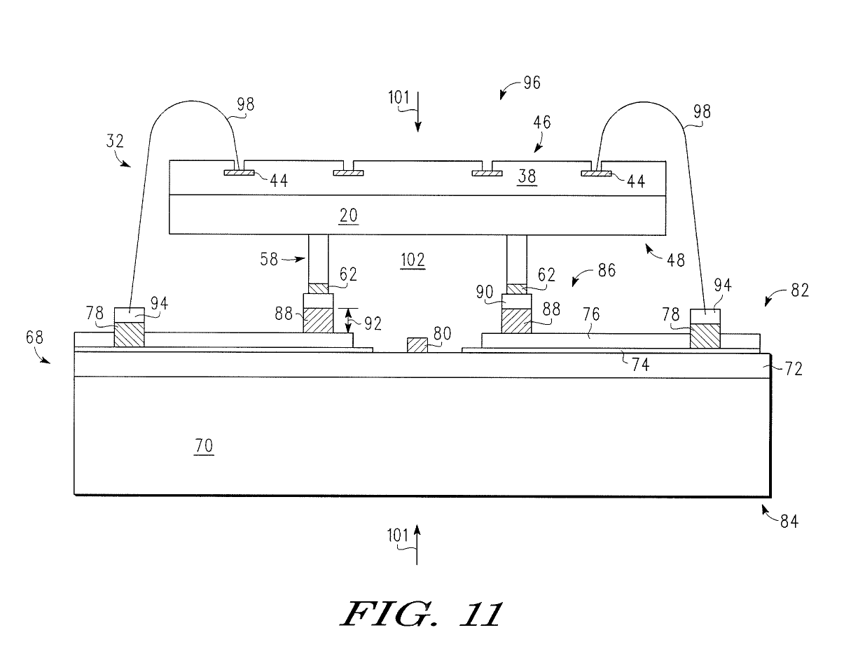

FIGS. 9 and 10 illustrate a MEMS die 68 that may also be formed on a substrate similar to the ones shown in FIG. 1. The MEMS die 68 includes a substrate portion 70, an insulating layer 72, a conducting layer 74, a dielectric film 76, bond pads 78, and a MEMS device element 80. The insulating layer 72 is made of, for example, silicon oxide and may be formed using CVD. The conductive layer 74 and the bonds pads 78 are made of, for example, aluminum that is formed using sputtering. Although not shown in detail, the conducting layer 74 includes a series of conductive traces that electrically connect the bond pads 78 to the MEMS device element 80. The dielectric film 76 may be made of silicon nitride (SiN) that is formed over the conducting layer 74 using, for example, CVD.

In the depicted embodiment, the MEMS device element 80 is formed on an exposed, central portion of the substrate portion 70. In one embodiment, the MEMS device element 80 may include an electromechanical component (e.g., a proof mass) of a MEMS device (or sensor) that is generally configured to sense physical, electrical, magnetic, environmental, and/or other conditions. The MEMS sensor may be a mechanical sensor (e.g., a vibration sensor, an accelerometer, or a stress/strain sensor), a magnetic field sensor, an electrical attribute sensor (e.g., a voltage sensor, a current sensor, an impedance or resistance sensor, a temperature sensor, a capacitance sensor, or an inductance sensor), or a switch or other actuating device. In a manner similar to the IC die 32 described above, the MEMS die 68 has a first (or upper or “active”) side 82 and a second (or lower or “inactive”) side 84.

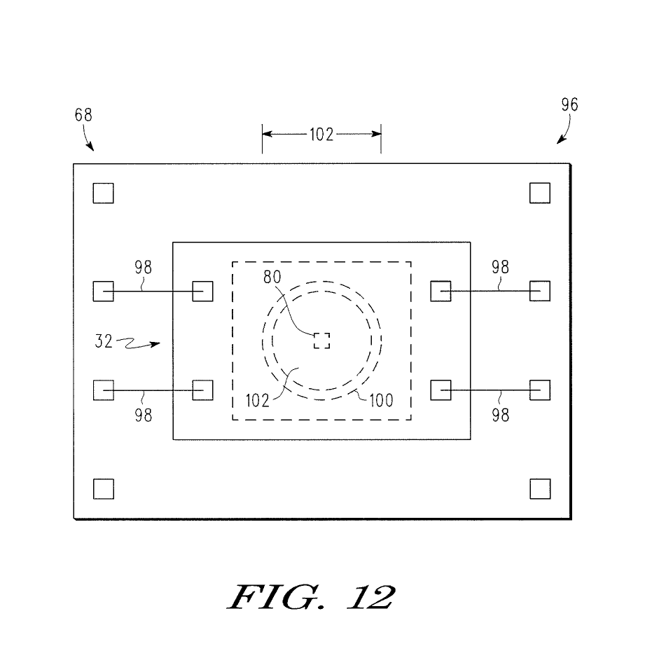

As shown in FIG. 10, the MEMS die 68 also includes a second structural support component 86. The second structural support component 86 includes a first portion 88 and a second portion 90, each of which may be substantially annular in shape (i.e., ring-shaped). The first portion 88 of the second structural support component 86 may be made of, for example, aluminum (Al) and formed using the same methods as, and substantially simultaneously with, the bond pads 88. The first portion 88 may have a height 92 of, for example, approximately 3 μm. The second portion 90 is made of, for example, a layer of titanium tungsten (TiW) that is deposited on the first portion 88 to a thickness of between approximately 1500 and 3200 Å and a layer of gold (Au) that is formed over the titanium tungsten to a thickness of approximately 1 μm. In the depicted embodiment, the formation of the second portion 90 may also be used to form pad caps 94 over the bond pads 78, which may be similar in composition to the second portion 90 of the second structural support component 90. In one embodiment, the MEMS die 68 is then singulated from its respective substrate via sawing or dicing (e.g., using a diamond saw and a pick and place machine). Alternatively, the MEMS die 68 may be singulated after the formation of the assembly shown in FIGS. 11 and 12.

FIGS. 11 and 12 illustrate a microelectronic assembly 96 according to one embodiment of the present invention. As shown, the microelectronic assembly 96 includes the IC die 32, the MEMS die 68, and wire bonds (or conductive members) 98. In one embodiment, the microelectronic assembly 96 is formed by positioning the IC die 32 over the MEMS die 68 such that the first structural support component 58 is aligned with and contacts the second structural support component 86 (i.e., such that the second side 48 of the IC die 32 “faces” the first side 82 of the MEMS die 84).

A force (represented by arrows 101) may be applied to the IC die 32 and the MEMS die 68 while the assembly 96 is heated (e.g., to approximately between 300° C. and 420° C.). In one embodiment, the force 101 is caused by placing a weight (e.g., 50 lbs.) over the IC die 32. The combination of the force 101 and the heating process causes a bond to be formed between first and second structural support components 58 and 86. In particular, in one embodiment, a eutectic bond is formed by the second portion 62 (e.g., tin) of the first structural support component 58 and the second portion 90 (e.g., titanium tungsten) of the second structural support component 86. As a result, a structural support member 100 (FIG. 12) is formed from the first and second structural support components 58 and 86. The structural support member 100 is, in the depicted embodiment, cylindrically shaped with a diameter 102 of, for example, between 100 and 200 μm, and a height (not shown) that is dependent on the heights of the first and second structural support components.

As will be appreciated by one skilled in the art, the materials used to form the first and second structural support components 58 and 86 may be varied such that different temperatures are used during the heating process to form the eutectic bond. For example, if the bond is formed from gold and tin (e.g., AuSn), the assembly 96 may be heated to between approximately 300 and 320° C. (e.g., 310° C.). If the bond is formed from gold and silicon (AuSi), the assembly 96 may be heated to between 360° C. and 420° C.

A MEMS cavity 102 is formed between the opposing sides of the structural support member 100, the second side 48 of the IC die 32, and the first side 82 of the MEMS die 68. As shown in FIGS. 11 and 12, the MEMS device element 80 is located within the MEMS cavity. In one embodiment, the bonding between the first and second structural support components 58 and 86 causes the MEMS cavity 102 to be hermetically sealed.

Still referring to FIGS. 11 and 12, the wire bonds 98 are positioned to interconnect the bond pads 44 on the IC die 32 and the bond pads 78 (and/or the bond pad caps 90) on the MEMS die 68, as well as electrically connect the integrated circuit within the IC die 32 to the MEMS device within the MEMS die 68. It should be noted that, in at least one embodiment, the structural support member 100 does not provide any electrical connections between the integrated circuit within the IC die 32 and the MEMS device within the MEMS die 68 (i.e., the electrical connections are provided by the wire bonds 98).

The formation of wire bonds 98 may substantially complete the formation of the microelectronic assembly 96. After final processing steps, the microelectronic assembly 96 may be further packaged and installed in various electrical systems, such as the electrical system of a vehicle.

During operation, the MEMS device of one embodiment within the MEMS die 68 detects various physical quantities (e.g., accelerations), depending on the exact type of MEMS device, and transmits appropriate electrical signals to the integrated circuit within the IC die 32, which may further process the signals before sending them to other components within the electrical system in which the microelectronic assembly 96 is installed.

One advantage of the microelectronic assembly and method described above is that a practical and inexpensive integration of conventional semiconductor processing techniques and MEMS device fabrication techniques it provided. In particular, the MEMS cavity may be formed without the use of a separate cap wafer. That is, an otherwise useful component (i.e., the IC die) is used to form the MEMS cavity. As a result, the number of components required is reduced, as is the overall cost of the assembly. Another advantage is that because the substrates (i.e., the IC die and the MEMS die) are stacked, the overall size (i.e., the “footprint”) of the assembly is reduced. A further advantage is that the processing steps (e.g., CMOS) used to form the structural support member reduce the likelihood that the MEMS device element will be contaminated. Therefore, the structural support member may be located closer to the MEMS device element, and the size of the assembly may be further reduced.

Other embodiments may use different methods and materials for forming the structural support member. For example, rather than deposited materials on the second side of the IC die, the substrate portion may be etched in such a way that the structural support member is formed from the semiconductor material of the wafer from which the IC die is formed (e.g., silicon). In such an embodiment, the substrate portion may form a silicon-gold eutectic bond, as is commonly understood. The structural support member may have other shapes (e.g., square) and sizes and may not form a hermetic seal around the MEMS device (and/or MEMS device element).

In one embodiment, the invention provides a method for forming a microelectronic assembly. First and second substrates are provided. Each substrate has first and second opposing sides. The first substrate has a first microelectronic device formed on the first side thereof, and the second substrate has a second microelectronic device formed on the first side thereof. The first and second substrates are interconnected with at least one support member such that the at least one support member is positioned between the second side of the first substrate and the first side of the second substrate. At least one conductive member is provided that electrically connects the first microelectronic device to the second microelectronic device.

The at least one support member may be formed on the second side of the first substrate, the first side of the second substrate, or a combination thereof. The first microelectronic device may be an integrated circuit. The second microelectronic device may be a microelectromechanical system (MEMS) device comprising a MEMS device element.

The at least one support member may include a metal. The at least one support member may surround the MEMS device element. The first substrate, the second substrate, and the at least one support member may jointly form a sealed MEMS cavity.

The at least one support member may interconnect first portions of the respective first and second substrates, and the at least one conductive member may interconnect second portions of the respective first and second substrates. The first portions of the first and second substrates may be central portions of the first and second substrates, and the second portions of the first and second substrates may be outer portions of the first and second substrates. The at least one conductive member may include a plurality of wire bonds.

In another embodiment, a method of forming a microelectronic assembly is provided. A first substrate having first and second opposing sides and an integrated circuit formed on the first side thereof is provided. A second substrate having first and second opposing sides and a microelectromechanical system (MEMS) device formed on the first side thereof is provided. At least one support member is formed on the second side of the first substrate, the first side of the second substrate, or a combination thereof. The second side of the first substrate and the first side of the second substrate are interconnected with the at least one support member such that the at least one support member is positioned between respective first portions of the first and second substrates. At least one conductive member is provided that electrically connects the integrated circuit to the MEMS device and contacts respective second portions of the first and second substrates.

The MEMS device may include a MEMS device element, and the at least one support member may surround the MEMS device element. The first substrate, the second substrate, and the at least one support member may jointly form a hermetically sealed MEMS cavity. The first portions of the first and second substrates may be central portions of the first and second substrates, and the second portions of the first and second substrates may be outer portions of the first and second substrates.

The forming of the at least one support member may include forming a first ring on the second side of the first substrate and forming a second ring on the first side of the second substrate. The interconnecting the second side of the first substrate and the first side of the second substrate with the at least one support member may include bonding the first ring to the second ring.

The bonding of the first ring to the second ring may include placing the first ring into contact with the second ring, heating the first and second rings, and applying a force to the first and second rings. The heating the first and second rings may include heating the first and second rings to a temperature of between 300 and 420° C.

In a further embodiment, a microelectronic assembly is provided. The microelectronic assembly includes a first substrate having first and second opposing sides and an integrated circuit formed on the first side thereof, a second substrate having first and second opposing sides and a microelectromechanical (MEMS) device formed on the first side thereof, a support member interconnecting the second side of the first substrate and the first side of the second substrate, the support member being sized and shaped such that the support member is between the second side of the first substrate and the first side of the second substrate, and a plurality of conductive members electrically interconnecting the integrated circuit and the MEMS device.

The support member may be positioned between respective first portions of the first and second substrates, and the plurality of conductive members may contact respective second portions of the first and second substrates. The MEMS device may include a MEMS device element on the first side of the second substrate. The first substrate, the second substrate, and the support member may jointly form an enclosed cavity, and the MEMS device element may be positioned within the cavity.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

1. A method for forming a microelectronic assembly comprising:
providing first and second substrates, each having first and second opposing sides, the first substrate having a plurality of transistors formed on the first side thereof and a plurality of insulating layers and conductors formed over the plurality of transistors, the second substrate having a microelectronic device formed on the first side thereof;
forming at least one support member on at least one of the second side of the first substrate and the first side of the second substrate;
interconnecting the first and second substrates with the at least one support member such that the at least one support member is positioned between the second side of the first substrate and the first side of the second substrate, wherein the at least one support member surrounds the microelectronic device after the interconnecting of the first and second substrates with the at least one support member; and
providing at least one conductive member that electrically connects the plurality of transistors to the microelectronic device.

2. The method of claim 1, wherein the forming of the at least one support member further comprises forming a first portion of a support member on the second side of the first substrate and forming a second portion of a support member on the first side of the second substrate.

3. The method of claim 1, wherein the plurality of transistors jointly form an integrated circuit.

4. The method of claim 1, wherein the microelectronic device is a microelectromechanical system (MEMS) device comprising a MEMS device element.

5. The method of claim 4, wherein the at least one support member comprises a metal.

6. The method of claim 5, wherein the at least one support member does not electrically interconnect the plurality of transistors and the MEMS device element.

7. The method of claim 4, wherein the first substrate, the second substrate, and the at least one support member jointly form a sealed MEMS cavity.

8. The method of claim 7, wherein the at least one support member interconnects first portions of the respective first and second substrates and the at least one conductive member interconnects second portions of the respective first and second substrates.

9. The method of claim 8, wherein the first portions of the first and second substrates are central portions of the first and second substrates and the second portions of the first and second substrates are outer portions of the first and second substrates.

10. The method of claim 9, wherein the at least one conductive member comprises a plurality of wire bonds.

11. A method of forming a microelectronic assembly comprising:
providing an integrated circuit die having first and second opposing sides and comprising a first substrate with a plurality of transistors formed on the first substrate and a plurality of insulating layers and conductors formed over the plurality of transistors;
providing a microelectromechanical system (MEMS) die having first and second opposing sides and comprising a second substrate with a MEMS device formed on the first side thereof;
forming at least one support member on the second side of the integrated circuit die, the first side of the MEMS die, or a combination thereof;
interconnecting the second side of the integrated circuit die and the first side of the MEMS die with the at least one support member such that the at least one support member is positioned between respective first portions of the integrated circuit and MEMS dies, wherein the at least one support member surrounds the MEMS device after the interconnecting of the integrated circuit die and the MEMS die with the at least one support member; and
providing at least one conductive member that electrically connects the plurality of transistors to the MEMS device and contacts respective second portions of the integrated circuit and MEMS dies.

12. The method of claim 11, wherein the MEMS device comprises a MEMS device element and the at least one support member is sized and shaped such that a gap is formed between the at least one support member and the MEMS device element.

13. The method of claim 12, wherein the integrated circuit die, the MEMS die, and the at least one support member jointly form a hermetically sealed MEMS cavity.

14. The method of claim 13, wherein the first portions of the integrated circuit and MEMS dies are central portions of the integrated circuit and MEMS dies and the second portions of the integrated circuit and MEMS dies are outer portions of the integrated circuit and MEMS dies.

15. The method of claim 14, wherein the forming of the at least one support member comprises forming a first ring on the second side of the integrated circuit die and forming a second ring on the first side of the MEMS die, and wherein the interconnecting the second side of the integrated circuit die and the first side of the MEMS die with the at least one support member comprises bonding the first ring to the second ring.

16. The method of claim 15, wherein the bonding of the first ring to the second ring comprises placing the first ring into contact with the second ring, heating the first and second rings, and applying a force to the first and second rings.

17. The method of claim 16, wherein the heating the first and second rings comprises heating the first and second rings to a temperature of between 300 and 420° C.

18. A microelectronic assembly comprising:
an integrated circuit die having first and second opposing sides and comprising a first substrate with a plurality of transistors formed on the first substrate and a plurality of insulating layers and conductors formed over the plurality of transistors;
a microelectromechanical system (MEMS) die having first and second opposing sides and comprising a second substrate with a MEMS device formed on the first side thereof;
a support member interconnecting the second side of the integrated circuit die and the first side of the MEMS die, the support member being sized and shaped such that the support member is between the second side of the integrated circuit die and the first side of the MEMS die and surrounds the MEMS device; and
a plurality of conductive members electrically interconnecting the plurality of transistors and the MEMS device.

19. The microelectronic assembly of claim 18, wherein the support member is positioned between respective first portions of the integrated circuit and MEMS dies and the plurality of conductive members contact respective second portions of the integrated circuit and MEMS dies, and wherein the support member does not electrically interconnect the plurality of transistors and the MEMS device.

20. The microelectronic assembly of claim 19, wherein the MEMS device comprises a MEMS device element on the first side of the MEMS die, the integrated circuit die, the MEMS die, and the support member jointly form an enclosed cavity, the MEMS device element being positioned within the cavity, and a gap is formed between the support member and the MEMS device element.
